(19) United States
(12) Patent Application Publication
(10) Pub. No.: US 2021/0151949 A1
(43) Pub. Date: May 20, 2021

(54) BONDING VERTICAL CAVITY SURFACE EMITTING LASER DIE ONTO A SILICON WAFER

(71) Applicant: Applied Materials, Inc., Santa Clara, CA (US)

(72) Inventors: Philip Hsin-Hua LI, San Jose, CA (US); Seshadri RAMASWAMI, Saratoga, CA (US); Kiyoung LEE, San Jose, CA (US)

(21) Appl. No.: 16/683,683

(22) Filed: Nov. 14, 2019

(51) Int. Cl. H01S 5/022; H01S 5/323

(52) U.S. Cl. CPC H01S 5/02268; H01S 5/02228; H01S 5/32316; H01S 5/32341; H01S 5/32391

(57) ABSTRACT

The disclosure describes techniques for forming an ohmic contact layer in a wafer containing CMOS devices and attaching a VCSEL die therein. A composite layer that forms the ohmic contact layer is selected based on the epitaxially-grown compound semiconductor material of the VCSEL die. The ohmic contact layer may not comprise gold, as gold introduces contamination in the rest of the CMOS process. The wafer may have an allocated area for accepting the VCSEL die. The allocated area may have a recess to facilitate placement of the VCSEL die.

### TECHNICAL FIELD

Embodiments of the disclosure relate generally to hybrid integration of compound semiconductor based photonic devices with silicon-based electronic devices.

### BACKGROUND

A semiconductor laser is a photonic device that emits a coherent beam of light of a certain wavelength through the process of stimulated emission. Vertical cavity surface emitting laser (VCSEL) is a type of semiconductor laser where the laser beam is emitted perpendicular to the top or bottom surface of the photonic device when driven by electrical current. A VCSEL may be integrated with a silicon-based electronic device that, among other things, electrically drives the VCSEL and mechanically supports the VCSEL without blocking the light emitting path.

The silicon-based electronic device usually has designated areas (bonding pads) for the VCSELs to be attached. The attachment of the VCSELs to the bonding pads may be done by flip-chip bonding or other wafer-scale bonding techniques. However, those hybrid integration techniques have not been easy to integrate with well-established silicon device processing technologies, such as complementary metal oxide semiconductor (CMOS) technology, that are suitable for large scale volume manufacturing for various reasons.

One reason for difficulty in integrating VCSELs to CMOS devices is material mismatch. VCSEL comprises a plurality of epitaxially-grown layers of III-V compound semiconductor material. The contact junction between the III-V material of the VCSEL and the silicon substrate of the electronic device should show characteristics as close as possible to a true ohmic contact, i.e. the contact junction should have a linear current-voltage (I-V) curve according to Ohm's law. However, some well-known ohmic contact-forming metals for III-V compound semiconductors, are incompatible with the CMOS process flow, as described further below in the detailed description section. This has impeded the mass adoption of III-V VCSEL bonding into silicon wafers in a CMOS fab.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later

The disclosure describes techniques for forming an ohmic contact layer in a silicon wafer containing CMOS devices and attaching a VCSEL die therein. A composite layer that forms the ohmic contact layer is selected based on the epitaxially-grown compound semiconductor material of the VCSEL die. The ohmic contact layer may not comprise gold, as gold introduces contamination in the rest of the CMOS process. The wafer may have an allocated area for accepting the VCSEL die. The allocated area may have a recess to facilitate placement of the VCSEL die.

More specifically, in one aspect of the present disclosure, a method of hybrid integration of a VCSEL with a semiconductor wafer is disclosed. The method comprises: allocating an area of an interconnect metal layer of a semiconductor wafer for bonding with a VCSEL die; coating a first bonding surface of the VCSEL die with a composite layer that forms ohmic contact with a material of the VCSEL die; coating at least a portion of the allocated area of the interconnect metal layer with the composite layer that forms ohmic contact with a material of the VCSEL die; placing the VCSEL die onto a surface of the portion of the allocated area of the interconnect metal layer that is coated with the composite layer; and, bonding the VCSEL die with the semiconductor wafer so that the VCSEL die is hybridly integrated with the semiconductor wafer.

In another specific aspect, a hybrid integrated circuit (IC) comprising a VCSEL bonded to a semiconductor wafer is disclosed. The circuit comprises: a VCSEL die with at least one bonding surface coated with a composite layer that forms ohmic contact with a material of the VCSEL die; an interconnect metal layer of a semiconductor wafer, wherein at least a portion of an area of the interconnect metal layer allocated for bonding with the VCSEL die is coated with the composite layer that forms ohmic contact with a material of the VCSEL die; and, a recess with sloped sidewalls bounding the area of the interconnect metal layer allocated for bonding with the VCSEL die, wherein the recess is formed by patterning a dielectric layer on top of the interconnect metal layer.

### BRIEF DESCRIPTION OF THE DRAWINGS

The present disclosure will be understood more fully from the detailed description given below and from the accompanying drawings of various embodiments of the disclosure.

FIG. 1 illustrates a longitudinal sectional view of a substrate with an interconnect layer on which an ohmic contact layer is deposited for a photonics device die attachment, according to an embodiment of the present disclosure.

FIG. 2 illustrates a longitudinal sectional view of a photonics device die with an ohmic contact layer at the bottom, according to an embodiment of the present disclosure.

FIG. 3 illustrates a longitudinal sectional view of showing the photonics device die bonded with the substrate, according to an embodiment of the present disclosure.

FIG. 4 illustrates a longitudinal sectional view of a silicon substrate with a recess bounding an area of the interconnect layer on which an ohmic contact layer is deposited for a VCSEL die attachment, according to an embodiment of the present disclosure.

FIG. 5 illustrates a bottom view of a VCSEL die with an ohmic contact layer at the bottom surface of the VCSEL die that faces the interconnect layer of a silicon substrate, according to an embodiment of the present disclosure.

FIG. 6 illustrates a longitudinal sectional view of showing the VCSEL die bonded with the recessed substrate and a second ohmic contact layer is formed at a redistributed line, according to an embodiment of the present disclosure.

FIG. 7 is a flow chart showing a process for hybridly integrating a VCSEL with a semiconductor wafer, in accordance with embodiments of the present disclosure.

### DETAILED DESCRIPTION

Embodiments of the present disclosure are directed to formation of ohmic contact between a photonic device and a CMOS wafer. The ohmic contact is formed by depositing a composite layer on portions of interconnect metal layers allocated in the CMOS wafer for bonding with the photonics device. The composite material is chosen based on the compound semiconductor material of the photonics device. Ohmic contact formation technique disclosed herein is integrated with the rest of the CMOS process flow by choosing suitable ohmic contact materials that are compatible with the CMOS process. Ohmic contact with the photonics device may be formed at a back-end-of-line (BEOL) stage of CMOS fabrication, and/or at a redistribution line (RDL) stage of CMOS fabrication.

VCSELs are a special type of photonics device that emit light perpendicular to its top and/or and bottom surfaces. VCSELs comprise a plurality of epitaxially-grown layers of III-V compound semiconductor materials, such as indium phosphide (InP), gallium arsenide (GaAs), gallium nitride (GaN) etc. The epitaxially-grown layers can be n-type or p-type, depending on the doping. Known ohmic contact for III-V compound semiconductors contain gold (Au). For example, for n-type GaAs, the ohmic contact material may comprise Ni/Ge/Au/Ni (meaning that a nickel (Ni) layer is adjacent to the n-type GaAs layer, followed by an Au layer, followed by a germanium (Ge) layer, followed by another Ni layer). Other alternatives may comprise Ge/Au/Ni, Au/Pt/Ti etc. For p-type GaAs, the ohmic contact layer may comprise Au/Zn/Au. For n-type InP, the ohmic contact layers may comprise Au/Ge or Au/Pt/Ti. For p-type InP, the ohmic contact layer may comprise Au/TiW/AuZn, AU/AuBe, Au/Pd/Zn/Pd etc. However, Au is considered a contaminant in the CMOS fab, as gold act as a deep-level trap and recombination center, i.e. charge carriers of opposite sign recombine at Au defects in silicon. Therefore, any ohmic contact having Au in cannot be formed in-line with the rest of the CMOS process. Consequently, the existing VCSEL-CMOS hybrid integration methods are not suitable for mass production leveraging the well-established CMOS process.

The present disclosure addresses this and other shortcomings of the current method by forming ohmic contacts with composite layers that do not include Au, and hence are compatible with a CMOS process. Advantages of the current method include, but are not limited to, cost reduction through streamlining the ohmic contact formation process as a part of the overall CMOS process flow, leading to high volume mass production of hybrid VCSEL-CMOS integrated devices. The ohmic contact formation process is suitable for bonding VCSELs onto a full scale wafer, such as a 300 mm silicon wafer.

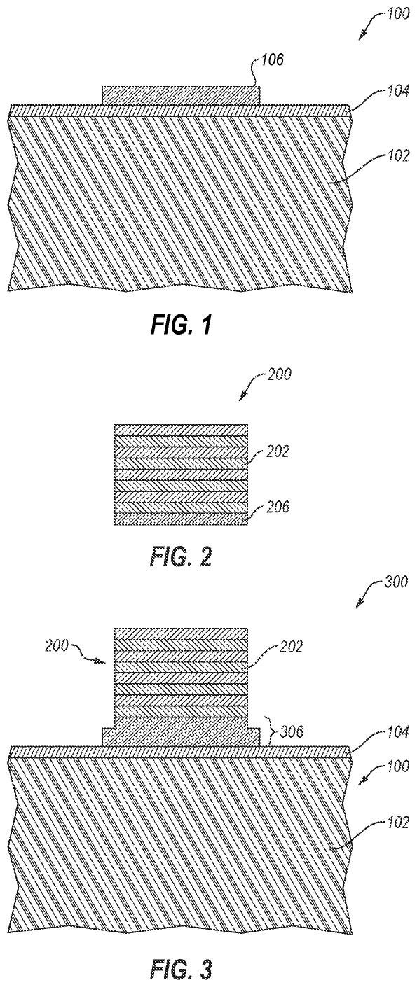

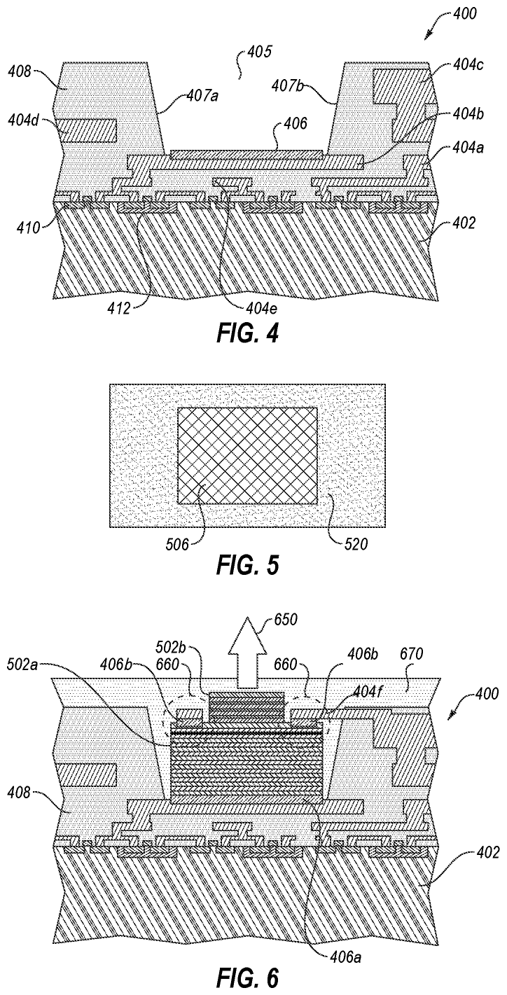

FIG. 1 illustrates a longitudinal sectional view of an embodiment 100 having a substrate with an interconnect layer on which an ohmic contact layer is deposited for a photonic device die attachment, according to an embodiment of the present disclosure. Substrate 102 may be a silicon wafer used for fabricating CMOS devices. Layer 104 may be a metallic interconnect layer. Interconnect layer 104 may be aluminum or copper or other metal suitable for the device fabrication process. Note that even though the interconnect layer 104 is shown adjacent to the substrate 102, in some embodiments (e.g., embodiment 400 shown in FIG. 4), the metallic interconnect layer may be a part of RDL layer that is not immediately adjacent to the substrate. A composite layer 106 may be deposited on top of the interconnect layer 104. In an example, the thickness of the composite layer 106 may be in the range of 1000-2000 Angstrom, but other values of thickness may be possible too. The composite layer 106 is patterned to form the bonding pad areas for the VCSELs. The material of the composite layer 106 is selected based on the material of the VCSEL, so that an ohmic contact can be formed between the VCSEL and the layer 106 deposited on the interconnect layer 104.

FIG. 2 illustrates a longitudinal sectional view of a VCSEL die 200 with an ohmic contact layer 206 at the bottom, according to an embodiment of the present disclosure. The VCSEL die 200 comprises alternating layers of epitaxially-grown III-V material, e.g., GaAs, InP, or GaN. The material of the alternating layers is labeled as 202. The alternating layers act as a Distributed Bragg Reflector (DBR) structure tailored for the target emission wavelength of the VCSEL. For example, GaAs-based VCSELs tend to emit lower wavelength light than the InP-based VCSELs, although the wavelength can be tuned by changing the doping level and layer thickness during the epitaxial growth. Typically, the ohmic contact layer 206 has the same composition as the composite layer 106 to which the VCSEL die 200 is bonded to. In some embodiments, the VCSEL die 200 does not have a separate ohmic contact layer 206, but the VCSEL material layer closest to the bonding pad composite layer 106 is designed to form an ohmic contact. In some embodiments, thickness of the composite layer 206 is in the same range as the thickness of the composite layer 206.

FIG. 3 illustrates a longitudinal sectional view of showing the VCSEL die 200 bonded with the substrate 102, according to an embodiment 300 of the present disclosure. Embodiment 300 comprises the ohmic contact layer 306 formed when layers 106 and 206 are bonded together, and typically followed by annealing at an optimum temperature to achieve low contact resistance that characterizes an ohmic contact. In some embodiments, thickness of the ohmic contact layer 306 may be in the range of 2000-5000 Angstrom, but other values of thickness are possible too.

As mentioned above, material of the composite layer 306 (which has the same composition as 106 and 206) is chosen based on the material 202 of the VCSEL die 200. For example, when the material 202 of the VCSEL die is n-type indium phosphide (InP), the composite layer 306 (which has the same composition as 106 and 206) may be chosen from one of the following: germanium/palladium (Ge/Pd), germanium/platinum (Ge/Pt), platinum/titanium (Pt/Ti), or tungsten-silicide (WSi). When the material 202 of the VCSEL die is p-type indium phosphide (InP), the composite layer 306 may be chosen from one of the following: germanium/palladium (Ge/Pd), germanium/platinum (Ge/Pt), platinum/titanium (Pt/Ti), tungsten-silicide (W Si), germanium/palladium/zinc/palladium (Ge/Pd/Zn/Pd), palladium/zinc/palladium (Pd/Zn/Pd), or palladium/antimony/zinc/palladium (Pd/Sb/Zn/Pd). When the material 202 of the VCSEL die is n-type gallium arsenide (GaAs), the composite layer 306 may be chosen from one of the following: germanium/palladium (Ge/Pd), germanium/platinum (Ge/Pt), platinum/titanium (Pt/Ti), tungsten-silicide (WSi), silicon/palladium (Si/Pd), palladium/indium/palladium (Pd/In/Pd), germanium/nickel (Ge/Ni), germanium/silver/nickel (Ge/Ag/Ni), copper/germanium (Cu/Ge), tungsten/indium (W/In), or silver/titanium (Ag/Ti). When the material 202 of the VCSEL die is p-type gallium arsenide (GaAs), the composite layer 306 may be chosen from one of the following: germanium/palladium (Ge/Pd), germanium/platinum (Ge/Pt), platinum/titanium (Pt/Ti), tungsten-silicide (W Si), silicon/nickel/manganese/nickel (Si/Ni/Mg/Ni), or palladium/antimony/manganese/palladium (Pd/Sb/Mn/Pd). When the material 202 of the VCSEL die is n-type gallium nitride (GaN), the composite layer 306 is chosen from one of the following: germanium/palladium (Ge/Pd), germanium/platinum (Ge/Pt), platinum/titanium (Pt/Ti), tungsten-silicide (WSi), or aluminum/titanium (Al/Ti). When the material 202 of the VCSEL die is p-type gallium nitride (GaN), the composite layer 306 is chosen from the following: germanium/palladium (Ge/Pd), germanium/platinum (Ge/Pt), platinum/titanium (Pt/Ti), or tungsten-silicide (WSi). Persons skilled in the art would appreciate that the lists of candidate materials to form the ohmic contact is not exhaustive. A particular material may be chosen based on experimentation of what creates an effective ohmic contact corresponding to a known VCSEL material while not disrupting the fabrication process flow of the silicon-based electronic circuit.

FIG. 4 describes an embodiment 400 showing a substrate 402 with individual electronic devices (e.g., transistors) fabricated therein. The substrate itself may be doped. In one illustrative embodiment, the substrate 402 may have regions 412 with a different doping than the substrate, forming “wells” (e.g. p-well) within which the sub-regions 410 reside. Sub-regions 410 may have a doping level different from the surrounding well 412, and/or different from the substrate itself. A dielectric layer 408 is formed on top of the devices. Interconnect layer 404 may be redistributed within the dielectric layer 408. For example, 404a, 404b, 404c, 404d, 404e are portions of the interconnect layer 404 that are redistributed.

A recess 405 may be created in the dielectric layer 408 formed on top of the interconnect layer to expose the portion of the interconnect metal layer 404b that is to be coated with the composite layer 406. Note that the sidewalls 407a and 407b of the recess 405 may be sloped, as shown in FIG. 4, to easily align and place the VCSEL die onto the composite layer 406 forming a first ohmic contact. Bonding-specific alignment marks may be included in the mask layout during the RDL process to make a second ohmic contact on a top side of the VCSEL die once the VCSEL die is bonded to the composite layer 406 within the recess 405.

FIG. 5 illustrates a bottom view of a VCSEL die with an ohmic contact layer at the bottom surface of the VCSEL die that faces the interconnect layer of a silicon substrate, according to an embodiment of the present disclosure. A VCSEL mesa 506 of a dimension that fits within the recess may be formed on a VCSEL substrate 520 that is larger than the mesa 506. The VCSEL substrate 520 represents a singulated die. The VCSEL substrate 520 facilitates in picking and placing the VCSEL die within the recess with the mesa side facing the composite layer 406. But once the VCSEL is bonded, the VCSEL substrate may be removed, i.e. the VCSEL substrate may work as a sacrificial layer. The ohmic contact layer at the bottom of the VCSEL die interfaces with the composite layer 406, and upon annealing, creates the combined bottom ohmic contact layer 406a shown in FIG. 6.

FIG. 6 illustrates a longitudinal sectional view of showing the VCSEL die bonded with the recessed substrate and a second ohmic contact layer is formed at a redistributed line, according to an embodiment of the present disclosure. The second ohmic contact regions are shown within the dashed lines 660 showing the top-side ohmic contact between layer 406b with the redistributed interconnect metal layer portion 404f extending from the interconnect metal layer portion labeled 404c in FIG. 4. Note that the second ohmic contact pattern may be an annulus formed on top of the VCSEL portion 502a (which may be a bottom DBR, while a top DBR portion 502b protrudes beyond and is surrounded by the top ohmic contact).

A void-free gap-filling material 670 is used as a dielectric overcoat to provide structural and environmental stability to the embodiment shown in FIG. 6. The material 670 is transparent to the emission wavelength of the VCSEL, such that laser beam 650 emerges from the top surface of the VCSEL. Note that in some embodiments, a different material is used for gap-filling between the silicon wafer and the VCSEL that accommodates the gap differences/tolerances, and a separate dielectric material is used for encapsulation.

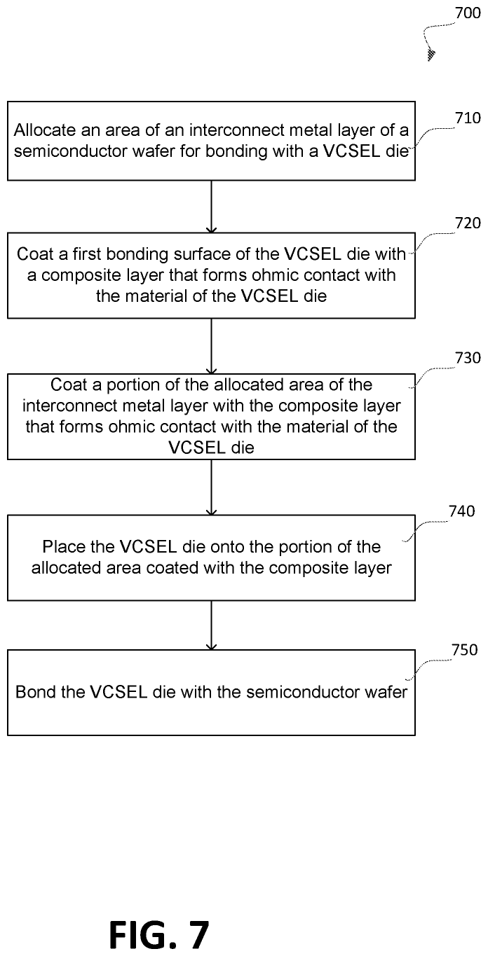

FIG. 7 shows a method 700 of hybridly integrating a VCSEL with a semiconductor wafer. The operations of method 700 may be performed by various manufacturing machines used in a fabrication process flow, e.g. a CMOS process flow. Note that the operations do not have to performed in the order show, and some operations may be optional. Other operations may be introduced in between the operations shown explicitly in FIG. 7.

At operation 710, an area of an interconnect metal layer of a semiconductor wafer is allocated for bonding with a VCSEL die. For example, an area of the layer 104 in FIGS. 1 and 3, or an area of layer 404b in FIG. 4 (bounded by the recess walls) is allocated for VCSEL bonding.

At operation 720, a first bonding surface of the VCSEL die is coated with a composite layer that forms ohmic contact with a material of the VCSEL die. For example, the layer 206 may be formed at the bottom of the VCSEL die 200. Note that, this step is optional, as a VCSEL die without a bottom ohmic contact may be directly bonded on layer 106 formed on the layer 104.

At operation 730, the allocated bonding area of the interconnect metal layer is coated with the composite layer that forms ohmic contact with a material of the VCSEL die. For example, layer 106 is formed on layer 104, depending on the material 202 of the VCSEL die 200 in FIGS. 1-3, or layer 406 is formed on layer 404b in FIG. 4, depending on the material of the VCSEL die (502a shown in FIG. 6).

At operation 740, the VCSEL die is placed onto a surface of the portion of the allocated area of the interconnect metal layer that is coated with the composite layer. Note that the recess in FIG. 4 facilitates in aligning the VCSEL die with the allocated bonding area. If there is no recess (as in FIGS. 1-3), additional alignment marks may be needed for placement of the VCSEL die onto the allocated bonding area on the interconnect layer.

At operation 750, the VSEL die is bonded with the semiconductor wafer. Bonding may be done by applying heat and pressure, and may be followed by annealing the bottom ohmic contact layer 406a at a target temperature.

Note that once the VCSEL die is physically placed at the allocated bonding bad, still further operations may be performed to form a top ohmic contact (e.g. the contact regions shown within the dashed circles 660 in FIG. 6). To form the top ohmic contact, a second bonding surface of the VCSEL die is coated with the composite layer (406b) that forms ohmic contact with a material of the VCSEL die. A second interconnect metal layer 404f is then formed that overlaps with the second bonding surface of the VCSEL die. The interconnect metal layer 404f may be deposited before the bonding step described at operation 750 above. The bonding and annealing of both the top and bottom ohmic contacts may be performed at the same time.

Additionally, the gaps between the recess and the VCSEL die may be filled with a void-free material (670). The void-free material may be planarized, as shown in FIG. 6. As mentioned before, the void-free material may be transparent to the emission wavelength of the VCSEL. The hybridly integrated VCSEL die and the semiconductor wafer may be encapsulated with the same void-free material 670 or a different dielectric material that is also transparent to the emission wavelength.

In the foregoing specification, implementations of the disclosure have been described with reference to specific example implementations thereof. It will be evident that various modifications can be made thereto without departing from the broader spirit and scope of implementations of the disclosure as set forth in the following claims. The specification and drawings are, accordingly, to be regarded in an illustrative sense rather than a restrictive sense.

What is claimed is:

1. A method of hybrid integration of a vertical cavity surface emitting laser (VCSEL) with a semiconductor wafer, the method comprising:
allocating an area of an interconnect metal layer of a semiconductor wafer for bonding with a VCSEL die;
coating a first bonding surface of the VCSEL die with a composite layer that forms ohmic contact with a material of the VCSEL die;
coating at least a portion of the allocated area of the interconnect metal layer with the composite layer that forms ohmic contact with a material of the VCSEL die;
placing the VCSEL die onto a surface of the portion of the allocated area of the interconnect metal layer that is coated with the composite layer; and
bonding the VCSEL die with the semiconductor wafer so that the VCSEL die is hybridly integrated with the semiconductor wafer.

2. The method of claim 1, further comprising:
selecting the composite layer based on the material of the VCSEL die.

3. The method of claim 2, wherein the composite layer does not contain gold (Au) in order to be compatible with a complementary metal oxide semiconductor (CMOS) process.

4. The method of claim 2, wherein the material of the VCSEL die is n-type indium phosphide (InP), and the composite layer is at least one of the following: germanium/palladium (Ge/Pd), germanium/platinum (Ge/Pt), platinum/titanium (Pt/Ti), or tungsten-silicide (WSi).

5. The method of claim 2, wherein the material of the VCSEL die is p-type indium phosphide (InP), and the composite layer is at least one of the following: germanium/palladium (Ge/Pd), germanium/platinum (Ge/Pt), platinum/titanium (Pt/Ti), tungsten-silicide (WSi), germanium/palladium/zinc/palladium (Ge/Pd/Zn/Pd), palladium/zinc/palladium (Pd/Zn/Pd), or palladium/antimony/zinc/palladium (Pd/Sb/Zn/Pd).

6. The method of claim 2, wherein the material of the VCSEL die is n-type gallium arsenide (GaAs), and the composite layer is at least one of the following: germanium/palladium (Ge/Pd), germanium/platinum (Ge/Pt), platinum/titanium (Pt/Ti), tungsten-silicide (WSi), silicon/palladium (Si/Pd), palladium/indium/palladium (Pd/In/Pd), germanium/nickel (Ge/Ni), germanium/silver/nickel (Ge/Ag/Ni), copper/germanium (Cu/Ge), tungsten/indium (W/In), or silver/titanium (Ag/Ti).

7. The method of claim 2, wherein the material of the VCSEL die is p-type gallium arsenide (GaAs), and the composite layer is at least one of the following: germanium/palladium (Ge/Pd), germanium/platinum (Ge/Pt), platinum/titanium (Pt/Ti), tungsten-silicide (WSi), silicon/nickel/manganese/nickel (Si/Ni/Mg/Ni), or palladium/antimony/manganese/palladium (Pd/Sb/Mn/Pd).

8. The method of claim 2, wherein the material of the VCSEL die is n-type gallium nitride (GaN), and the composite layer is at least one of the following: germanium/palladium (Ge/Pd), germanium/platinum (Ge/Pt), platinum/titanium (Pt/Ti), tungsten-silicide (WSi), or aluminum/titanium (Al/Ti).

9. The method of claim 2, wherein the material of the VCSEL die is p-type gallium nitride (GaN), and the composite layer is at least one of the following: germanium/palladium (Ge/Pd), germanium/platinum (Ge/Pt), platinum/titanium (Pt/Ti), or tungsten-silicide (WSi).

10. The method of claim 2, wherein the interconnect metal layer comprises copper or aluminum.

11. The method of claim 1, wherein coating the selected area of the interconnect metal layer with the composite layer is performed during a back-end-of-line (BEOL) fabrication stage of the semiconductor wafer.

12. The method of claim 1, wherein allocating the area further comprises:
creating a recess in a dielectric layer formed on top of a substrate to expose the portion of the interconnect metal layer that is to be coated with the composite layer.

13. The method of claim 12, wherein the recess has sloped sidewalls to facilitate placement of the VCSEL die.

14. The method of claim 12, wherein one or more alignment marks are included in a mask layout for distributing the interconnect metal layer, wherein the alignment marks facilitate insertion of the VCSEL die into the recess.

15. The method of claim 12, further comprising:
after bonding, removing a sacrificial substrate attached to the VCSEL die.

16. The method of claim 16, further comprising:
coating a second bonding surface of the VCSEL die with the composite layer that forms ohmic contact with a material of the VCSEL die;
forming a second interconnect metal layer that at least partially overlaps with the second bonding surface of the VCSEL die; and
bonding the second bonding surface of the VCSEL die with the second interconnect metal layer.

17. The method of claim 16, wherein the second interconnect metal layer is the redistributed line (RDL).

18. The method of claim 16, further comprising:
filling gaps between the recess and the VCSEL die with a void-free material; and
planarizing the void-free material.

19. The method of claim 17, further comprising:
encapsulating the hybridly integrated VCSEL die and the semiconductor wafer with a top dielectric that is transparent to an emission wavelength of the VCSEL.

20. A hybrid integrated circuit (IC) comprising a VCSEL bonded to a semiconductor wafer, the circuit comprising:
a VCSEL die with at least one bonding surface coated with a composite layer that forms ohmic contact with a material of the VCSEL die;
an interconnect metal layer of a semiconductor wafer, wherein at least a portion of an area of the interconnect metal layer allocated for bonding with the VCSEL die is coated with the composite layer that forms ohmic contact with a material of the VCSEL die; and
a recess with sloped sidewalls bounding the area of the interconnect metal layer allocated for bonding with the VCSEL die, wherein the recess is formed by patterning a dielectric layer on top of the interconnect metal layer.
